(19) United States
(12) Patent Application Publication
(10) Pub. No.: US 2021/0296203 A1
(43) Pub. Date: Sep. 23, 2021

(54) HEAT DISSIPATION SUBSTRATE, PREPARATION METHOD AND APPLICATION THEREOF, AND ELECTRONIC COMPONENT

(71) Applicant: BYD COMPANY LIMITED, Shenzhen, Guangdong (CN)

(72) Inventor: Junlan LIAN, Shenzhen (CN)

(73) Assignee: BYD COMPANY LIMITED, Shenzhen (CN)

(21) Appl. No.: 16/475,011

(22) PCT Filed: Dec. 8, 2017
(86) PCT No.: PCT/CN2017/115140

§ 371 Date: Jun. 28, 2019

(30) Foreign Application Priority Data
Dec. 29, 2016 (CN) 201611249663.2

(51) Int. Cl. H01L 23/373; H01L 21/48

(52) U.S. Cl. CPC H01L 23/3735; H01L 21/4807

(57) ABSTRACT

A heat dissipation substrate includes: a metal-ceramic composite board, where the metal-ceramic composite board is a metal layer wrapping a ceramic body; and a metal oxide layer integrated with the metal layer and formed in an area of at least a part on an outer surface of the metal layer; and a soldering area on which the metal oxide layer is not formed and that is used to connect with a copper substrate and bear a chip.

### CROSS-REFERENCE TO RELATED APPLICATIONS

This application is the U.S. national phase entry of PCT Application No. PCT/CN2017/115140, filed Dec. 8, 2017, which claims priority to and benefits of Chinese Patent Application No. 201611249663.2, filed with the State Intellectual Property Office of P. R. China on Dec. 29, 2016. The entire contents of the above-referenced applications are incorporated herein by reference.

### FIELD

The present disclosure relates to the field of heat dissipation substrates for encapsulating electronic devices, and specifically, to a heat dissipation substrate, a method for preparing same, an application of same, and an electronic device.

### BACKGROUND

In a process of preparing an electronic device, an encapsulating material usually needs to be used to resolve a thermal failure problem of an electronic circuit such as a chip. The encapsulating material not only needs to play a role of being capable of soldering a copper substrate and bearing a chip, but also needs to be responsible for heat dissipation at the same time. Because the encapsulating material is in contact with a cooling liquid in a process of performing heat exchange, the encapsulating material is further required to have anticorrosion performance.

Therefore, during actual use, the encapsulating material is usually applied in a substrate form, and it is required that a surface of the substrate is used for soldering the copper substrate and bearing the chip, and can have a soldering function; and another opposite surface is in contact with the cooling liquid to implement heat dissipation, and can have an anticorrosion function. To satisfy this requirement, a current usual solution is to perform nickel plating on the entire substrate. However, this imposes a strict requirement on quality of a surface of the substrate. If there are a pit, a sand hole, and the like, nickel plating cannot cover up these defects. As a result, a soldering yield rate is low. Although the thickness of a plating layer may be increased through design of a plating layer structure, production costs are increased evidently.

In the prior art, in the process of preparing an electronic device, a nickel plating method is taken to resolve the heat dissipation problem and the anticorrosion problem of the encapsulating material. However, there are defects that the product yield rate is low and costs are high.

### SUMMARY

The present disclosure is to resolve the foregoing problem existing in a heat dissipation substrate used for encapsulating an electronic device, so as to provide a heat dissipation substrate, a method for preparing same, an application of same, and an electronic device.

The present disclosure further provides a heat dissipation substrate. The heat dissipation substrate includes: a metal-ceramic composite board, where the metal-ceramic composite board is a metal layer wrapping a ceramic body; and on the outer surface of the metal layer, at least a portion of the region is formed a metal oxide layer integrated with the metal layer, and a soldering area on which the metal oxide layer is not formed and that is used to connect with a copper substrate and bear a chip.

The present disclosure further provides a method for preparing a heat dissipation substrate of the present disclosure, including: directly performing metal oxidation on a metal-ceramic composite board, where the metal-ceramic composite board is a composite board material in which a metal layer wraps a ceramic body; forming a metal oxide layer integrated with the metal layer on an outer surface of the metal layer; and performing laser etching on an area of at least a part of the metal oxide layer, and removing the metal oxide layer to form a soldering area.

The present disclosure further provides an application of a heat dissipation substrate of the present disclosure in an electronic device.

The present disclosure further provides an electronic device, where the electronic device includes: a heat dissipation substrate, where the heat dissipation substrate has a soldering area on which a metal oxide layer is not formed; and a first soldering layer, a first copper substrate, a lining board, a second copper substrate, a second soldering layer, and a chip sequentially stacked on a surface of the soldering area, where the chip is connected to the second copper substrate through a conducting wire; and the heat dissipation substrate is a heat dissipation substrate of the present disclosure.

Through the foregoing technical solutions, direct oxidation is performed on the outer surface of the metal layer of the metal-ceramic composite board in situ to form the metal oxide layer, the heat dissipation substrate having heat dissipation, anticorrosion, and soldering functions may be provided, and the heat dissipation substrate has a larger bonding strength, and may better bear the chip, so as to overcome the defects of the nickel plating method taken in the prior art. Through the foregoing technical solutions, the obtained heat dissipation substrate may be provided with better soldering performance. That is, through a sessile drop test, the heat dissipation substrate has better wetting performance. Moreover, the provided heat dissipation substrate has better anticorrosion performance through a neutral salt spray test. Moreover, the heat dissipation substrate has the soldering area formed, and a soldering metal layer may be saved in the formed electronic device, to reduce the thickness of the electronic device.

Other features and advantages of the disclosure are described in detail in the subsequent specific implementations.

### BRIEF DESCRIPTION OF THE DRAWINGS

The accompanying drawing is used to further understand the disclosure and constitute a part of the specification, and is used to explain the disclosure together with the following specific implementations, but does not constitute a limitation on the disclosure. In the accompanying drawings:

FIG. 1 is a schematic structural diagram of a heat dissipation substrate;

FIG. 2 is a schematic structural diagram of an electronic device; and

FIG. 3 is a schematic diagram of a contact angle θ in a sessile drop test.

Description of the reference signs:

| | | |
|---|---|---|
| 1 metal-ceramic composite | 2 metal oxide layer | 3 soldering |
| board | | area |
| 4 a first soldering layer | 5 a first copper substrate | 6 lining board |
| 7 a second copper substrate | 8 a second soldering layer | 9 chip |
| 10 conducting wire | | |

### DETAILED DESCRIPTION

Specific implementations of the disclosure are described in detail below. It should be understood that the specific implementations described herein are merely used to describe and explain the present disclosure rather than limit the present disclosure.

Endpoints of all ranges and all values disclosed herein are not limited to the precise ranges or values, and these ranges or values should be understood as including values close to these ranges or values. For value ranges, endpoint values of the ranges, an endpoint value of each range and an independent point value, and independent point values may be combined with each other to obtain one or more new value ranges, and these value ranges should be considered as being specifically disclosed herein.

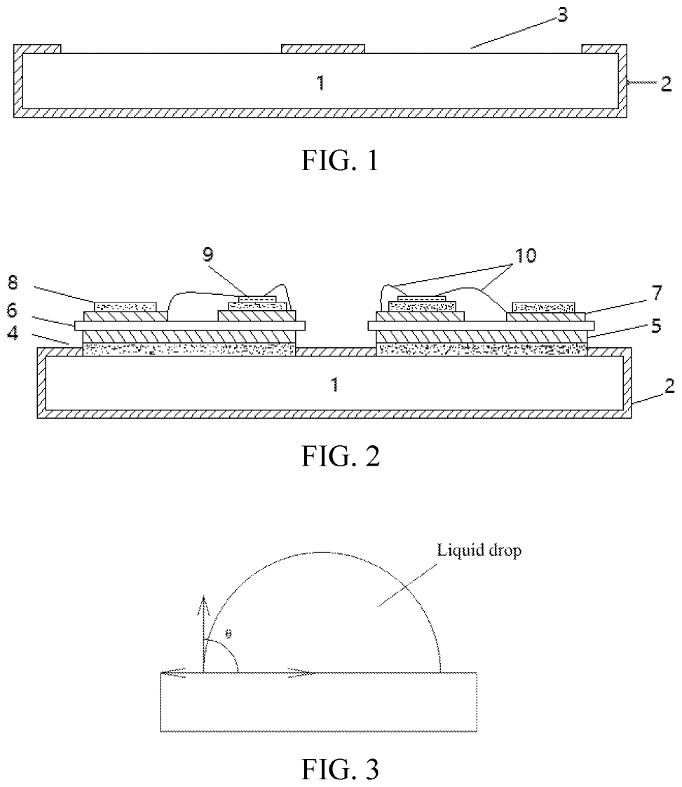

The present disclosure is to provide a heat dissipation substrate, as shown in FIG. 1. The heat dissipation substrate includes: a metal-ceramic composite board 1, where the metal-ceramic composite board is a metal layer wrapping a ceramic body; and on the outer surface of the metal layer, at least a portion of the region is formed a metal oxide layer 2 integrated with the metal layer, and a soldering area 3 on which the metal oxide layer is not formed and that is used to connect with a copper substrate and bear a chip.

According to the present disclosure, the metal oxide layer is formed by directly oxidizing the metal layer, to wrap the metal layer. The metal oxide layer is formed by directly oxidizing the metal layer in situ, and may have a larger bonding strength. Photographing and observation may be performed through a metallographic microscope, and it is observed on a section of the heat dissipation substrate provided in the present disclosure that there is no boundary between the metal layer of the metal-ceramic composite board and the metal oxide layer. However, if a metal oxide layer is obtained by coating or depositing a metal layer and then oxidizing the metal layer, it is observed through the metallographic microscope that an evident boundary exists between the metal layer of the metal-ceramic composite board and the formed metal oxide layer. An area of the metal layer that is not wrapped by the metal oxide layer forms the soldering area. Further, the metal oxide layer may be provided with a soldering surface (or surface A) and a heat dissipation surface (or surface B). The soldering surface (or surface A) and the heat dissipation surface (or surface B) may be two opposite surfaces on the heat dissipation substrate, and are usually two surfaces on the heat dissipation substrate that have maximum areas. Optionally, the soldering area is disposed on only the soldering surface of the metal oxide layer, and may be further used to solder the copper substrate and the chip. The heat dissipation surface may be in contact with a cooling liquid and is used for heat dissipation. Optionally, the soldering area is disposed on the metal oxide layer on a side of the heat dissipation substrate; and the metal oxide layer on another side is used to be in contact with the cooling liquid, to perform heat dissipation.

In the present disclosure, optionally, the soldering area only needs to satisfy further soldering with the copper substrate. The soldering area is “inserted” into the metal oxide layer, so that when an electronic device is further prepared, the copper substrate may be connected to the heat dissipation substrate without a soldering metal layer, and the thickness of the electronic device may be reduced, to provide better encapsulating performance.

In the present disclosure, in the provided heat dissipation substrate, through the foregoing metal oxide layer directly formed in situ and the soldering area that is disposed on the soldering surface and that is “inserted” into the metal oxide layer, the heat dissipation substrate may be provided with better bonding strength, soldering performance, and anticorrosion performance at the same time.

According to the present disclosure, for the heat dissipation substrate, a substrate material regularly used in an encapsulating material of an electronic device, for example, a base material containing metal may be selected as a base material, and the metal-ceramic composite board may be selected as a base material. Then, the metal oxide layer and the soldering area are formed on this base material. Optionally, the ceramic body is selected from a SiC ceramic body or a Si ceramic body; and the metal layer is an Al metal layer, an Mg metal layer, or a Ti metal layer. The metal-ceramic composite board may be commercially available. The thickness of the ceramic body may be not particularly limited, and may be approximately 3 mm.

According to the present disclosure, the metal oxide layer is formed by the metal layer in situ, and the metal oxide layer is an oxide corresponding to metal used for the metal layer. The metal oxide layer is an aluminum oxide layer, a magnesium oxide layer, or a titanium oxide layer.

According to the present disclosure, it is only required that the thickness of each layer included in the heat dissipation substrate can implement the heat dissipation function, the anticorrosion function, and the functions of connecting to the copper substrate and bearing the chip. Optionally, the thickness of the metal layer is 20 μm to 500 μm; and the thickness of the metal oxide layer is 5 μm to 300 μm. In the present disclosure, the thickness of the metal oxide layer is less than the thickness of the metal layer.

According to the present disclosure, the metal layer and the metal oxide layer in the heat dissipation substrate may have better bonding strength between each other. Optionally, a bonding strength between the metal oxide layer and the metal layer is measured to be above 4B according to a cross-cut test.

The present disclosure is further to provide a method for preparing a heat dissipation substrate of the present disclosure, including: directly performing metal oxidation on a metal-ceramic composite board, where the metal-ceramic composite board is a composite board material in which a metal layer wraps a ceramic body; forming a metal oxide layer integrated with the metal layer on an outer surface of the metal layer; and performing laser etching on an area of at least a part of the metal oxide layer, and removing the metal oxide layer to form a soldering area.

According to the present disclosure, a conventional material applicable to encapsulation of an electronic device may be selected, and may be a material containing metal. For example, the metal-ceramic composite board may be used as a base material for forming the heat dissipation substrate. The ceramic body may be selected from a SiC ceramic body or a Si ceramic body; and the metal layer may be selected from an Al metal layer, an Mg metal layer, or a Ti metal layer. The thickness of the ceramic body may be not particularly limited, and may be approximately 3 mm. The thickness of the metal layer may be 20 μm to 500μm. Further, the metal oxide layer may be directly formed in situ on the outer surface of the metal layer in the metal-ceramic composite board through the metal oxidation. If the metal layer is an Al metal layer, an aluminum oxide layer is obtained. If the metal layer is an Mg metal layer, a magnesium oxide layer is obtained. If the metal layer is a Ti metal layer, a titanium oxide layer is obtained.

According to the present disclosure, the metal oxidation may include a plurality of specific implementation methods, as long as a metal oxide layer satisfying a required thickness is formed on the outer surface of the metal layer in the metal-ceramic composite board. Optionally, a method for the metal oxidation includes chemical oxidation, anodic oxidation, or micro-arc oxidation. It is only required that the metal oxidation is implemented to obtain the metal oxide layer having a sufficient thickness. Optionally, the thickness of the metal oxide layer formed through the metal oxidation is 1 μm to 50 μm.

Specifically, a method and a condition for chemical oxidation include: removing surface oil contamination and a surface oxide layer from the metal-ceramic composite board, and then placing the metal-ceramic composite board in a chemical oxidation solution for 5 min to 10 min. The chemical oxidation solution contains 50 ml/L to 80 ml/L of phosphoric acid, and 20 g/L to 25 g/L of chromic anhydride (chromium trioxide). The temperature of the chemical oxidation solution is 30° C. to 40° C.

A method and a condition for anodic oxidation include: removing surface oil contamination and a surface oxide layer from the metal-ceramic composite board, then placing the metal-ceramic composite board in a chemical oxidation solution, and electrifying the chemical oxidation solution for 10 min to 30 min to perform sealing treatment. The sealing treatment may be performed by using hot water. The oxidation solution is a solution containing 180 g/L to 220 g/L of sulfuric acid, the temperature is −5° C. to 25° C., the voltage is 10 V to 22 V, and the current density is 0.5 A/dm² to 2.5 A/dm².

A method and a condition for micro-arc oxidation include: removing surface oil contamination from the metal-ceramic composite board, then placing the metal-ceramic composite board in a micro-arc oxidation solution in a micro-arc oxidation tank, electrifying the micro-arc oxidation solution to perform micro-arc oxidation, and performing hot water sealing after micro-arc oxidation is completed. The micro-arc oxidation solution is usually a weakly basic solution, and may contain a silicate, a phosphate, a borate, or the like. The temperature of micro-arc oxidation is controlled to be 20° C. to 60° C., and the voltage may be usually controlled to be 400 V to 750 V. The micro-arc oxidation may alternatively be implemented by using a low-voltage micro-arc oxidation technology.

According to the present disclosure, the laser etching is used to form the soldering area “inserted” into the metal oxide layer on the soldering surface of the heat dissipation substrate provided in the present disclosure. As described above, the soldering area may be formed in a partial area on a side surface of the heat dissipation substrate, and is used to further solder the copper substrate and the chip. Optionally, in the laser etching, infrared laser whose wavelength is 1000 nm to 5000 nm is used, and emitted energy of the infrared laser is 20 kW to 80 kW. Optionally, the wavelength is 1064 nm. The distance of the laser etching is a focal distance of laser. Infrared laser etching is performed under the foregoing condition, and the soldering area may be better formed in the metal oxide layer.

In the present disclosure, the foregoing preparation method may further include: first pre-treating the metal-ceramic composite board, degreasing and dewaxing the metal-ceramic composite board, further removing the oxide layer formed on the outer surface of the metal layer of the metal-ceramic composite board due to natural oxidation, and then performing the metal oxidation in the foregoing preparation method provided in the present disclosure. For example, degreasing and dewaxing may be performed by immersing the metal-ceramic composite board in an ethyl alcohol solution for 5 min, or immersing the metal-ceramic composite board in degreasing powder U-151 (Atotech) for 5 min at 50° C. A method and a condition for removing the oxide layer formed due to natural oxidation may be: immersing the metal-ceramic composite board for 3 min in an aqueous sodium hydroxide solution whose concentration is 50 g/L, or immersing the metal-ceramic composite board for 1 min at a room temperature in a tank liquid configured by hot-dipping electrolytic deterging powder U-152.

In the present disclosure, the foregoing preparation method may further include: after the metal oxidation step is completed, sealing and drying the obtained board material, and then performing the metal spraying. The function of sealing may be to seal holes formed during oxidation. Sealing may be implemented by using a boiling water sealing method. Drying may be performed for 20 min to 30 min at 80° C. to 100° C.

The present disclosure is further to provide an application of a heat dissipation substrate of the present disclosure in an electronic device. The heat dissipation substrate of the present disclosure may be used as an encapsulating material in an electronic device.

The present disclosure is further to provide an electronic device. As shown in FIG. 2, the electronic device includes: a heat dissipation substrate 1, where the heat dissipation substrate has a soldering area 3 on which a metal oxide layer 2 is not formed; and a first soldering layer 4, a first copper substrate 5, a lining board 6, a second copper substrate 7, a second soldering layer 8, and a chip 9 sequentially stacked on a surface of the soldering area, where the chip is connected to the second copper substrate through a conducting wire 10; and the heat dissipation substrate is a heat dissipation substrate of the present disclosure. The heat dissipation substrate includes: a metal-ceramic composite board in which a metal layer wraps a ceramic body; and a metal oxide layer integrated with the metal layer and formed in an area of at least a part on an outer surface of the metal layer, where an area of another part is a soldering area on which the metal oxide layer is not formed.

In the electronic device of the present disclosure, the heat dissipation substrate provides functions of bearing the chip and dissipating heat of the chip. A side of the heat dissipation substrate on which the soldering area is formed is further provided with a plurality of stacked layers, to bear the chip; and another opposite side does not have the soldering area, may be in contact with a cooling liquid, and is used as a cooling surface to dissipate heat of the chip. Because the cooling liquid is corrosive, and the cooling surface of the heat dissipation substrate has the metal oxide layer formed in situ by directly oxidizing the metal layer, an anticorrosion function may be provided.

In the present disclosure, layers are sequentially stacked on the soldering area, to finally bear the chip. The first soldering layer is used to connect the first copper substrate to the metal layer of the metal-ceramic composite board. The first soldering layer may be formed through a tin soldering method by using a tin paste. The second soldering layer is used to connect the second copper substrate to the chip. The second soldering layer may also be formed through a tin soldering method by using a tin paste.

In the present disclosure, the first copper substrate and the second copper substrate are copper substrates regularly used in the art. The second copper substrate may form a conductive trace, and then the chip and the second copper substrate are connected through the conducting wire, to satisfy a use requirement of the chip.

In the present disclosure, the lining board is disposed between the first copper substrate and the second copper substrate, and may be a lining board used to encapsulate the electronic device and regularly used in the art.

In the electronic device of the present disclosure, a method for forming the first soldering layer, the first copper substrate, the lining board, the second copper substrate, and the second soldering layer may be a regular method in the art, and details are not described herein again. The conducting wire may also connect the chip and the second copper substrate by using a regular method in the art, and details are not described herein again.

The disclosure is described in detail below by using embodiments.

In the following embodiments and comparison examples, a metal-ceramic composite board is an Al-SiC composite board from HWT Technology Co., Ltd.

Soldering performance passes through a sessile drop technique (Sessile Drop) test: A melted solder liquid is dripped onto a surface of a soldering metal layer of a clean and smooth heat dissipation substrate, and after a balanced and stable state is reached, photographing is performed as shown in FIG. 3. A photograph is enlarged, a contact angle θ is directly measured, and a corresponding liquid-solid interfacial tension is calculated through the angle θ. The contact angle θ in the method may be used to represent whether wetting is qualified: if θ<90°, it is referred to as wetting; if θ>90°, it is referred to as non-wetting; if θ=0°, it is referred to as complete wetting; and if θ=180°, it is referred to as complete non-wetting. Wetting represents good soldering performance, and is indicated by using “OK”; and non-wetting represents poor soldering performance.

Anticorrosion performance of the heat dissipation substrate passes through a neutral salt spray test: The heat dissipation substrate is inclined by 15° to 30°, so that a to-be-tested surface can accept salt spray at the same time; conditions are (5±0.1)% NaCl solution; the pH value is between 6.5 to 7.2; the salt spray settling amount is 1 to 2 ml/80 cm²·h; and the temperature is 35±2° C. The surface of the tested sample is observed, and time points at which bubbling and rusting occur are recorded.

The bonding strength between a metal oxide layer and a metal-ceramic composite board of a heat dissipation substrate in the embodiments, and the bonding strength between a nickel layer and a metal-ceramic composite board of a heat dissipation substrate in the comparison examples are measured according to a cross-cut test. 100 square grids of 1 mmx 1 mm are cut, by using a cross-cutter, on a surface of a heat dissipation substrate on which a neutral salt spray test is performed for 24 h. A transparent adhesive tape of a model 600 produced by USA 3M Corporation is used to smoothly bond the square grids without any void, and then is lifted up at a highest speed by an angle of 60°, to observe whether metal shedding exists at a scratch edge and score. Scoring standards are: if there is no shedding, the score is 5B; if the shedding amount is between 0 to 5 wt %, the score is 4B; if the shedding amount is between 5 to 15 wt %, the score is 3B; if the shedding amount is between 15 to 35 wt %, the score is 2B; if the shedding amount is between 35 to 65 wt %, the score is 1B; and if the shedding amount is above 65 wt %, the score is 0 B.

### Embodiment 1

This embodiment describes a heat dissipation substrate of the present disclosure and a method for preparing same.

An Al—SiC composite board (the thickness of SiC is 3 mm, and the thickness of Al is 200 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation, to obtain a to-be-oxidized substrate.

The to-be-oxidized substrate is placed in an oxidation solution containing 200 g/L of sulfuric acid (98 wt %), and anodic oxidation is performed for 10 min at 15° C., 10 V, and 2.5 A/cm³, to obtain an aluminum oxide layer whose thickness is 100 μm; then sealing is performed with purified water for 5 min at 95° C., and then for 30 min at 80° C.; and a to-be-etched substrate is obtained.

A surface of the to-be-etched substrate is determined as a soldering surface, and laser etching is performed by focusing at power of 50 kW with infrared laser having a wavelength of 1024 nm to remove a part of the aluminum oxide layer to form a soldering area, so as to obtain the heat dissipation substrate.

Tests of soldering performance, anticorrosion performance, and bonding performance are performed on the heat dissipation substrate, and results are seen in Table 2.

### Embodiment 2

This embodiment describes a heat dissipation substrate of the present disclosure and a method for preparing same.

An Al—SiC composite board (the thickness of SiC is 3 mm, and the thickness of Al is 300 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation, to obtain a to-be-oxidized substrate.

The to-be-oxidized substrate is placed in an oxidation solution containing 180 g/L of sulfuric acid (98 wt %), and anodic oxidation is performed for 30 min at −5° C., 22 V, and 1 A/cm³; an aluminum oxide layer whose thickness is 30 μm is obtained; then sealing is performed with purified water for 5 min at 95° C., and then for 30 min at 80° C.; and a to-be-etched substrate is obtained.

A surface of the to-be-etched substrate is determined as a soldering surface, and laser etching is performed by focusing at power of 20 kW with infrared laser having a wavelength of 1024 nm to remove a part of the aluminum oxide layer to form a soldering area, so as to obtain the heat dissipation substrate.

Tests of soldering performance, anticorrosion performance, and bonding performance are performed on the heat dissipation substrate, and results are seen in Table 2.

### Embodiment 3

This embodiment describes a heat dissipation substrate of the present disclosure and a method for preparing same.

An Al—SiC composite board (the thickness of SiC is 3 mm, and the thickness of Al is 200 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation, to obtain a to-be-oxidized substrate.

The to-be-oxidized substrate is placed in an oxidation solution containing 200 g/L of sulfuric acid (98 wt %), and anodic oxidation is performed for 10 min at 25° C., 18 V, and 0.5 A/cm³; an aluminum oxide layer whose thickness is 50 μm is obtained; then sealing is performed with purified water for 5 min at 95° C., and then for 30 min at 80° C.; and a to-be-etched substrate is obtained.

A surface of the to-be-etched substrate is determined as a soldering surface, and laser etching is performed by focusing at power of 80 kW with infrared laser having a wavelength of 1024 nm to remove a part of the aluminum oxide layer to form a soldering area, so as to obtain the heat dissipation substrate.

Tests of soldering performance, anticorrosion performance, and bonding performance are performed on the heat dissipation substrate, and results are seen in Table 2.

### Embodiment 4

This embodiment describes a heat dissipation substrate of the present disclosure and a method for preparing same.

An Al-SiC composite board (the thickness of SiC is 3 mm, and the thickness of Al is 20 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation, to obtain a to-be-oxidized substrate.

The to-be-oxidized substrate is placed in an oxidation solution containing 200 g/L of sulfuric acid (98 wt %), and anodic oxidation is performed for 5 min at 15° C., 10 V, and 2.5 A/cm³; an aluminum oxide layer whose thickness is 5μm is obtained; then sealing is performed with purified water for 5 min at 95° C., and then for 30 min at 80° C.; and a to-be-etched substrate is obtained.

A surface of the to-be-etched substrate is determined as a soldering surface, and laser etching is performed by focusing at power of 60 kW with infrared laser having a wavelength of 1024 nm to remove a part of the aluminum oxide layer to form a soldering area, so as to obtain the heat dissipation substrate.

Tests of soldering performance, anticorrosion performance, and bonding performance are performed on the heat dissipation substrate, and results are seen in Table 2.

### Embodiment 5

This embodiment describes a heat dissipation substrate of the present disclosure and a method for preparing same.

An Al—SiC composite board (the thickness of SiC is 3 mm, and the thickness of Al is 500 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation, to obtain a to-be-oxidized substrate.

The to-be-oxidized substrate is placed in a chemical oxidation solution containing 60 ml/L of phosphoric acid and 25 g/L of chromic anhydride, chemical oxidation is performed for 5 min at 35° C., to obtain an aluminum oxide layer whose thickness is 300 μm; then the aluminum oxide layer is cleaned up and dried for 30 min at 80° C.; and a to-be-etched substrate is obtained.

A surface of the to-be-etched substrate is determined as a soldering surface, and laser etching is performed by focusing at power of 50 kW with infrared laser having a wavelength of 1024 nm to remove a part of the aluminum oxide layer to form a soldering area, so as to obtain the heat dissipation substrate.

Tests of soldering performance, anticorrosion performance, and bonding performance are performed on the heat dissipation substrate, and results are seen in Table 2.

### Embodiment 6

On the heat dissipation substrate of Embodiment 1, a first soldering layer is formed on a soldering area through a tin soldering method by using a tin paste; and then a first copper substrate, a lining board, a second copper substrate, and a second soldering layer are sequentially stacked on the first soldering layer, to connect with a chip, the chip is connected to the second copper substrate through a leading wire, to obtain an electronic device whose structure is shown in FIG. 2, and the total thickness of the electronic device is 4.8 mm.

### COMPARISON EXAMPLE 1

An Al-SiC composite board (the thickness of SiC is 3 mm, and the thickness of Al is 200 μm) is immersed in ERPREP Flex (Atotech) for 5 min at 50° C. to perform degreasing and dewaxing, and then immersed for 3 min in a tank liquid configured by Actane 4322s to perform deoxidation; and a treated substrate is obtained.

Nickel plating is performed on the treated substrate according to a process shown in Table 1, to obtain a nickel layer whose thickness is 10 μm; and a heat dissipation substrate is obtained. Chemicals are products commercially available from Cookson-Enthone Chemistry.

TABLE 1

| Procedure | Chemical | Temperature | Time | |
|---|---|---|---|---|
| Deterging | ENPLATE BS | Room temperature | 3 | min |
| Water washing | Purified water | Room temperature | 1 | min |
| Zinc | ENPLATE BS EN | Room temperature | 1 | min |
| galvanizing 1 | | | | |
| Water washing | Purified water | Room temperature | 1 | min |
| Zinc stripping | 50% nitric acid | Room temperature | 1 | min |
| Water washing | Purified water | Room temperature | 1 | min |
| Zinc | ENPLATE BS EN | Room temperature | 30 | s |
| galvanizing 1 | | | | |
| Water washing | Purified water | Room temperature | 1 | min |
| Basic nickel | ENPLATE ENI-120 | Room temperature | 10 | min |
| Water washing | Purified water | Room temperature | 1 | min |
| Nickel plating | ENPLATE ENI-807 | 85° C. | 60 | min |
| Water washing | Purified water | Room temperature | 1 | min |
| Drying | | 80° C. | 30 | min |

Tests of soldering performance, anticorrosion performance, and bonding performance are performed on the heat dissipation substrate, and results are seen in Table 2.

### COMPARISON EXAMPLE 2

According to the method of Embodiment 6, the heat dissipation substrate prepared in the comparison example 1 is used to encapsulate a chip, and a first soldering layer, a first copper substrate, a lining board, a second copper substrate, a second soldering layer, and the chip are sequentially stacked on a nickel layer, to prepare an electronic device. The total thickness of the electronic device is 4.83 mm.

TABLE 2

| | Soldering | Anticorrosion | Bonding |
|---|---|---|---|
| Number | performance | performance | performance |
| Embodiment 1 | OK | 500 h | 5B |
| Embodiment 2 | OK | 700 h | 5B |
| Embodiment 3 | OK | 500 h | 5B |
| Embodiment 4 | OK | 400 h | 4B |
| Embodiment 5 | OK | 450 h | 4B |
| Comparison example 1 | OK | 24 h | 3B |

It may be seen from the embodiments, the comparison example, and data results in Table 2 that, the heat dissipation substrate provided in the present disclosure may have good anticorrosion performance, soldering performance, and bonding performance at the same time. Moreover, the heat dissipation substrate provided in the present disclosure has a simpler technology, is industrialized conveniently, and is reduced in use of nickel, costs and discharging of nickel liquid waste are reduced, and the present disclosure provides the heat dissipation substrate with better performance in a more environmentally-friendly manner. However, the heat dissipation substrate obtained in the comparison examples may satisfy soldering performance, but anticorrosion performance and bonding performance are both quite poor.

Moreover, it may be seen by comparing Embodiment 6 with the comparison example 2 that, the heat dissipation substrate provided in the present disclosure may be prepared to reduce the thickness of the electronic device.

What is claimed is:

1. A heat dissipation substrate, comprising:
a metal-ceramic composite board, wherein the metal-ceramic composite board is a metal layer wrapping a ceramic body;
a metal oxide layer integrated with the metal layer and formed in an area of at least a part on an outer surface of the metal layer; and
a soldering area on the outer surface of the metal layer for connecting with a copper substrate and bearing a chip, on which the metal oxide layer is not formed.

2. The substrate according to claim 1, wherein the metal oxide layer is formed by directly oxidizing the metal layer.

3. The substrate according to claim 1, wherein the ceramic body is a SiC ceramic body or a Si ceramic body; the metal layer is an Al metal layer, an Mg metal layer, or a Ti metal layer; and the metal oxide layer is an aluminum oxide layer, a magnesium oxide layer, or a titanium oxide layer.

4. The substrate according to claim 1, wherein a thickness of the metal layer is about 20 μm to about 500 μm; and the a thickness of the metal oxide layer is about 5 μm to about 300 μm.

5. The substrate according to claim 1, wherein a bonding strength between the metal oxide layer and the metal layer is measured to be above about 4B according to a cross-cut test.

6. A method for preparing the heat dissipation substrate according to claim 1, comprising: directly performing metal oxidation on a metal-ceramic composite board, wherein the metal-ceramic composite board is a composite board material in which a metal layer wraps a ceramic body; forming a metal oxide layer integrated with the metal layer on an outer surface of the metal layer; and
performing laser etching on an area of at least a part of the metal oxide layer, and removing the metal oxide layer to form a soldering area.

7. The method for preparing the heat dissipation substrate according to claim 6, wherein the metal oxidation comprises chemical oxidation, anodic oxidation, or micro-arc oxidation.

8. The method for preparing the heat dissipation substrate according to claim 6, wherein in the laser etching, infrared laser whose wavelength is about 1000 nm to about 5000 nm is used, and emitted energy of the infrared laser is about 20 kW to about 80 kW.

9. The method for preparing the heat dissipation substrate according to claim 8, wherein in the laser etching, infrared laser whose wavelength is about 1064 nm is used.

10. The method for preparing the heat dissipation substrate according to claim 6 or 7, wherein the thickness of the metal oxide layer formed through the metal oxidation is about 5 μm to about 300 μm.

11. (canceled)

12. An electronic device, comprising:
a heat dissipation substrate, wherein the heat dissipation substrate has a soldering area on which a metal oxide layer is not formed; and
a first soldering layer, a first copper substrate, a lining board, a second copper substrate, a second soldering layer, and a chip sequentially stacked on a surface of the soldering area, wherein the chip is connected to the second copper substrate through a conducting wire; and
the heat dissipation substrate is the heat dissipation substrate according to claim 1.

13. The substrate according to claim 2, wherein the ceramic body is a SiC ceramic body or a Si ceramic body; the metal layer is an Al metal layer, an Mg metal layer, or a Ti metal layer; and the metal oxide layer is an aluminum oxide layer, a magnesium oxide layer, or a titanium oxide layer.

14. The substrate according to claim 2, wherein a thickness of the metal layer is about 20 μm to about 500 μm; and a thickness of the metal oxide layer is about 5 μm to about 300 μm.

15. The substrate according to claim 2, wherein a bonding strength between the metal oxide layer and the metal layer is measured to be above about 4B according to a cross-cut test.

16. A method for preparing the heat dissipation substrate according to claim 15, comprising: directly performing metal oxidation on a metal-ceramic composite board, wherein the metal-ceramic composite board is a composite board material in which a metal layer wraps a ceramic body; forming a metal oxide layer integrated with the metal layer on an outer surface of the metal layer; and
performing laser etching on an area of at least a part of the metal oxide layer, and removing the metal oxide layer to form a soldering area.

17. The method according to claim 16, wherein the metal oxidation comprises chemical oxidation, anodic oxidation, or micro-arc oxidation.

18. The method according to claim 17, wherein in the laser etching, infrared laser whose wavelength is about 1000 nm to about 5000 nm is used, and emitted energy of the infrared laser is about 20 kW to about 80 kW.

19. The method according to claim 18, wherein in the laser etching, infrared laser whose wavelength is about 1064 nm is used.

20. The method according to claim 17, wherein the thickness of the metal oxide layer formed through the metal oxidation is about 5 μm to about 300 μm.
